(19) United States
(12) Patent Application Publication
(10) Pub. No.: US 2022/0066273 A1
(43) Pub. Date: Mar. 3, 2022

(54) LIGHT CONTROL FILM AND MANUFACTURING METHOD THEREOF

(71) Applicants: NITTO DENKO CORPORATION, Ibaraki-shi, Osaka (JP); National Institute of Advanced Industrial Science and Technology, Tokyo (JP)

(72) Inventors: Kenta Watanabe, Ibaraki-shi, Osaka (JP); Nozomi Fujino, Ibaraki-shi, Osaka (JP); Hideyuki Yonezawa, Ibaraki-shi, Osaka (JP); Akiko Sugino, Ibaraki-shi, Osaka (JP); Yasusei Yamada, Nagoya-shi, Aichi (JP); Kazuki Yoshimura, Nagoya-shi, Aichi (JP)

(73) Assignees: NITTO DENKO CORPORATION, Ibaraki-shi, Osaka (JP); National Institute of Advanced Industrial Science and Technology, Tokyo (JP)

(21) Appl. No.: 17/422,876

(22) PCT Filed: Jan. 29, 2020
(86) PCT No.: PCT/JP2020/003172

§ 371 Date: Jul. 14, 2021

(30) Foreign Application Priority Data
Jan. 30, 2019 (JP) 2019-014905

(51) Int. Cl. G02F 1/15; G02F 1/19; C23C 14/00

(52) U.S. Cl. CPC G02F 1/15; C23C 14/0036; G02F 1/19

(57) ABSTRACT

A light-modulation film (1) includes a light-modulation layer (30) and a catalyst layer (40) in this order on a polymer film substrate (10). A surface layer (70) may be disposed on the catalyst layer. The state of the light-modulation layer reversibly changes between a transparent state due to hydrogenation and a reflective state due to dehydrogenation. The catalyst layer promotes hydrogenation and dehydrogenation of the light-modulation layer. An arithmetic mean roughness of the surface of the catalyst layer is preferably 16 nm or less. A thickness of the light-modulation layer is preferably 2 to 20 times the thickness of the catalyst layer.

### TECHNICAL FIELD

The present invention relates to a light-modulation film which includes a hydrogen-activation-type light-modulation layer and a catalyst layer on a transparent film substrate, and a manufacturing method of the light-modulation film.

### BACKGROUND ART

Light-modulation elements are used for window panes of buildings and vehicles, interior materials, and the like. Particularly in recent years, demand and expectation for light-modulation elements have been increased from the viewpoints of reducing a cooling and heating load, reducing a lighting load, improving comfort, and so on. A hydrogen-activation-type light-modulation element switches between transmission and reflection of light by hydrogenation and dehydrogenation of a light-modulation material. The hydrogen-activation-type light-modulation element can reflect light from outside to prevent inflow of heat, and thus is excellent in heat shielding property and contributes to excellent energy saving effect. In addition, an area of the hydrogen-activation-type light-modulation element is readily increased, since it is able to switch between hydrogenation and dehydrogenation by a gas chromic system.

As hydrogen-activation-type light-modulation materials capable of reversibly switching between a transparent state and a reflective state by hydrogenation and dehydrogenation, rare earth metals, alloys of a rare earth metal and magnesium, alloys of an alkaline earth metal and magnesium, and alloys of a transition metal and magnesium are known. Particularly, when a magnesium alloy is used as the light-modulation material, a light-modulation element having a high light transmittance in a transparent state is obtained because magnesium hydride has a visible light transmittance. In a hydrogen-activation-type light-modulation element, a catalyst layer is disposed in proximity to a light-modulation layer. The catalyst layer has a function of promoting hydrogenation and dehydrogenation of the light-modulation layer. As the catalyst layer, palladium, a palladium alloy, platinum, a platinum alloy or the like is used.

It is known that when switching between a transparent state by hydrogenation and a reflective state by dehydrogenation is repeated, switching characteristics of a hydrogen-activation-type light-modulation material may be deteriorated due to migration, oxidation or the like of a material constituting the light-modulation layer. In particular, magnesium and a magnesium alloy are easily oxidized, and therefore it is important to prevent oxidation of the light-modulation layer in improvement of light-modulation performance and improvement of switching durability.

Patent Document 1 discloses a light-modulation element including a light-modulation layer and a catalyst layer on a glass substrate, and has a hydrogen-permeable antireflection layer provided on the catalyst layer. The antireflection layer has a function of reducing reflection at a surface of the light-modulation element to increase the transmittance. In addition, by providing an antireflection layer formed of a material having a barrier property against water and oxygen, oxidation of the light-modulation layer can be prevented.

Patent Document 2 discloses a light-modulation film including a light-modulation layer and a catalyst layer on a film substrate, and describes that when the light-modulation layer is deposited on the film substrate by sputtering, the light-modulation layer is oxidized by outgas or the like from the film substrate. Patent Document 2 proposes that by imparting a barrier property against outgas from a substrate with an oxide layer used as a light-modulation layer at the initial stage of deposition, oxidation of the light-modulation layer provided thereon is prevented.

### PRIOR ART DOCUMENTS

### Patent Documents

Patent Document 1: Japanese Patent Laid-Open No. 2014-26262

Patent Document 2: Japanese Patent Laid-Open No. 2016-218445

### SUMMARY OF THE INVENTION

### Problems to be Solved by the Invention

As described in Patent Document 2, unlike a case where a glass substrate is used, formation of a light-modulation layer on a film substrate may have a problem that the light-modulation layer is oxidized by outgas and transmitted gas from the film substrate. In addition, studies by the present inventors have revealed that a light-modulation film in which a light-modulation layer and a catalyst layer are disposed on a film substrate tends to have lower switching durability as compared to a light-modulation element using a glass substrate even when a surface layer having an oxygen barrier property as described in Patent Document 1 is provided. In view of such problems, an object of the present invention is to provide a hydrogen-activation-type light-modulation film having improved switching durability.

### Means for Solving the Problems

A light-modulation film of the present invention includes a light-modulation layer and a catalyst layer in this order on a polymer film substrate. The light-modulation layer is a layer, the state of which reversibly changes between a transparent state by hydrogenation and a reflective state by dehydrogenation. The light-modulation layer is a thin-film containing a metal such as rare earth metal, an alloy of a rare earth metal and magnesium, an alloy of alkaline earth metal and magnesium, and an alloy of a transition metal and magnesium, or a hydride or an oxide thereof. The catalyst layer promotes hydrogenation and dehydrogenation of the light-modulation layer. The light-modulation layer and the catalyst layer are formed by a sputtering method.

An arithmetic mean roughness Ra of the surface of the catalyst layer is preferably 16 nm or less. For example, by adjusting the ratio between the thickness of the light-modulation layer and the thickness of the catalyst layer formed on the light-modulation layer, the arithmetic mean roughness of the surface of the catalyst layer can be reduced. The thickness of the light-modulation layer is preferably 2 to 20 times the thickness of the catalyst layer. In addition, reduction of the pressure during sputtering deposition of the light-modulation layer tends to decrease the Ra of the surface of the light-modulation layer and decrease the Ra of the surface of the catalyst layer formed thereon. The pressure during sputtering deposition of the light-modulation layer is preferably 0.3 Pa or less.

A surface layer may be disposed on the catalyst layer. The thickness of the surface layer is, for example, 10 to 300 nm. The surface layer is formed by, for example, a wet method.

### Effect of the Invention

The light-modulation film of the present invention has small surface irregularities of the catalyst layer, and therefore has a good coverage with the surface layer and excellent switching durability.

### BRIEF DESCRIPTION OF THE DRAWINGS

FIG. 1 is a schematic sectional view showing one embodiment of light-modulation film.

FIG. 2 is a schematic sectional view showing one embodiment of light-modulation film.

FIG. 3 is a schematic sectional view showing one embodiment of light-modulation film.

### MODE FOR CARRYING OUT THE INVENTION

[Configuration of Light-Modulation Film]

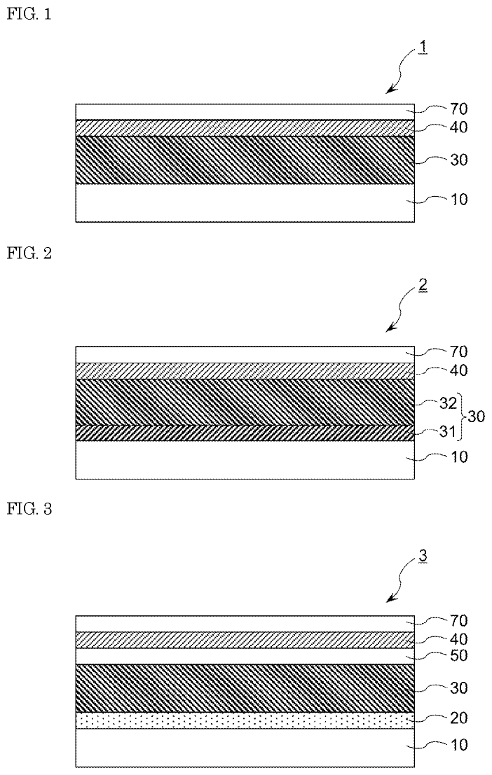

FIG. 1 is a schematic sectional view showing one embodiment of light-modulation film. The light-modulation film 1 includes a light-modulation layer 30 and a catalyst layer 40 on a polymer film substrate 10. It is preferable a surface layer 70 is provided on the catalyst layer 40.

<Film Substrate>

The polymer film substrate 10 may be transparent or opaque. A transparent plastic material is preferable as a material of the polymer film substrate for making the light-modulation film light-transmissive when the light-modulation layer is in a hydrogenated state. Examples of the plastic material include polyesters such as polyethylene terephthalate, polyolefins, cyclic polyolefins such as norbornene-based cyclic polyolefins, polycarbonate, polyether sulfone, and polyarylates.

The thickness of the polymer film substrate 10 is not particularly limited. The thickness of the polymer film is generally about 2 to 500 μm, and is preferably about 20 to 300 μm. A surface of the polymer film substrate 10 may be provided with an easily adhesive layer, an antistatic layer, a hard coat layer and the like. In addition, a surface of the polymer film substrate 10 may be subjected to an appropriate adhesion treatment such as a corona discharge treatment, an ultraviolet irradiation treatment, a plasma treatment, sputtering etching treatment or the like for improving adhesion with the light-modulation layer 30.

The arithmetic mean roughness Ra of the polymer film substrate 10 on the light-modulation layer 30-formed side is preferably 5 nm or less, more preferably 3 nm or less, further preferably 1 nm or less. When the surface roughness of the film substrate is reduced, film quality in the initial stage of deposition of the light-modulation layer is likely to be uniform. The arithmetic mean roughness Ra is calculated based on a roughness curve extracted from a three-dimensional surface shape measured by vertical scanning low coherence interferometry (ISO25178).

<Light-Modulation Layer and Catalyst Layer >

A light-modulation film is obtained by sequentially depositing a light-modulation layer 30 and a catalyst layer 40 on the polymer film substrate 10.

The material of the light-modulation layer 30 is not particularly limited as long as it contains a chromic material, the state of which is reversibly changed between a transparent state by hydrogenation and a reflective state by dehydrogenation. Specific examples of the material that constitutes the light-modulation layer include rare earth metals such as Y, La, Gd and Sm, alloys of a rare earth metal and magnesium, alloys of an alkaline earth metal such as Ca, Sr or Ba and magnesium, and alloys of a transition metal such as Ni, Mn, Co or Fe and magnesium. It is preferable that the light-modulation layer 30 contains magnesium for securing excellent transparency in hydrogenation state, and an alloy of a rare earth metal element and magnesium is more preferable from the viewpoint of securing both transparency and durability. The light-modulation layer 30 may contain an element other than the above-mentioned alloy as a minor component.

The metal or alloy that constitutes the light-modulation layer 30 contains a metal element which is transformed into a transparent state by hydrogenation, and is transformed back into a reflective state by releasing hydrogen. For example, magnesium is transformed into transparent MgH₂ when hydrogenated, and is transformed back into Mg with a metallic reflection when dehydrogenated.

The catalyst layer 40 on the light-modulation layer 30 has a function of promoting hydrogenation and dehydrogenation of the light-modulation layer 30. The switching speed in switching from the reflective state to the transparent state (hydrogenation of the light-modulation layer) and switching from the transparent state to the reflective state (dehydrogenation of the light-modulation layer) is increased by disposing the catalyst layer 40.

The material of the catalyst layer 40 is not particularly limited as long as the catalyst layer 40 has a function of promoting hydrogenation and dehydrogenation of the light-modulation layer 30, and for example, it is preferable that catalyst layer 40 includes at least one metal selected from palladium, platinum, a palladium alloy and a platinum alloy. In particular, palladium is preferably used because it has high hydrogen permeability.

The method for depositing the light-modulation layer 30 and catalyst layer 40 is not particularly limited, and for example, deposition methods such as a sputtering method, a vacuum vapor deposition method, an electron beam vapor deposition method, a chemical vapor deposition (CVD) method, a chemical bath deposition (CBD) method and a plating method can be employed. Among them, a sputtering method is preferable because a uniform and dense film can be deposited. Particularly, when a roll-to-roll sputtering apparatus is used, and deposition is performed while a long polymer film substrate is continuously moved in the longitudinal direction, productivity of the light-modulation film can be improved. In roll-to-roll sputtering, the light-modulation layer 30 and the catalyst layer 40 can be deposited in one film conveyance when a plurality of cathodes are arranged along the circumferential direction of one deposition roll, or a sputtering apparatus including a plurality of deposition rolls is employed. By successively depositing the light-modulation layer 30 and the catalyst layer 40, productivity can be improved, and degradation of the light-modulation layer due to oxidation can be suppressed because the catalyst layer 40 is deposited before the deposition surface of the light-modulation layer 30 is exposed to an oxidizing atmosphere.

It is preferable that after the inside of the sputtering apparatus is loaded with a roll-shaped film substrate and before sputtering deposition is started, the inside of the sputtering apparatus is evacuated to remove impurities such as organic gases generated from the film substrate. By removing gases in the apparatus and in the film substrate beforehand, oxidation due to incorporation of oxygen, moisture and the like into the light-modulation layer 30 can be suppressed. The degree of vacuum (ultimate vacuum) of the inside of the apparatus before the start of sputtering deposition is, for example, 1×10⁻² Pa or less, preferably 5×10⁻³ Pa or less, more preferably 1×10⁻³ Pa or less, further preferably 5×10⁻⁴ Pa or less, particularly preferably 5×10⁻⁵ Pa or less.

A metal target is used for deposition of the light-modulation layer 30 on the polymer film substrate 10. When an alloy layer is deposited as the light-modulation layer, an alloy target may be used, or a plurality of metal targets may be used. In addition, an alloy layer may also be formed using a target (split target) in which a plurality of metal plates are arranged and bonded on a backing plate in such a manner that an erosion portion has a predetermined area ratio. When a plurality of metal targets are used, an alloy layer having a desired composition can be formed by adjusting an electric power applied to each target. The light-modulation layer is deposited while an inert gas is introduced.

As in the case with the light-modulation film 2 shown in FIG. 2, an oxidation region 31 may be formed in the light-modulation layer 30 on an interface between the substrate 10. Since a metal oxide formed by sputtering easily forms a dense film, the oxide region 31 can exert an effect of blocking outgas and transmitted gas from the film substrate 10 when the oxidized region 31 is formed in the initial stage of deposition of the light-modulation layer 30. In other words, since the oxidized region 31 of the light-modulation layer 30 at the interface with the film substrate 10 functions as a sacrificial layer, oxidation of the light-modulation region 32 situated on the catalyst layer 40 side can be suppressed to maintain high light-modulation performance. Thus, when the light-modulation layer 30 is deposited so as to be in contact with the film substrate 10, it is preferable to form the light-modulation layer 30 having the oxidized region 31 with an oxygen content of 50 atom % or more on the film substrate 10 side, and a light-modulation region 32 with an oxygen content of less than 50 atom % on the oxidized region 31.

When the light-modulation layer 30 has the oxidized region 31 on the interface side with the film substrate 10, the thickness thereof is not particularly limited. For ensuring that the oxidized region is a continuous film, the thickness of the oxidized region 31 is preferably 2 nm or more. On the other hand, when the thickness of the oxidized region is excessively large, productivity and light-modulation performance tend to be deteriorated, and therefore the thickness of the oxidized region is preferably 100 nm or less. When the light-modulation layer 30 is deposited so as to be in contact with the film substrate 10, the thickness of the oxidized region is more preferably from 4 to 80 nm, further preferably from 6 to 60 nm. The thickness of the oxidized region formed in the initial stage of deposition can be controlled by adjusting the substrate temperature, the gas introduction amount, the process pressure, the metal composition of the target, and the like during deposition of the light-modulation layer.

It is preferable that the oxygen content in the vicinity of an interface of the light-modulation layer 30 on the catalyst layer 40 side is as small as possible. Specifically, the oxygen content within a range of 5 nm from an interface of the light-modulation layer 30 on the catalyst layer 40 side is preferably less than 50 atom %, more preferably 45 atom % or less, further preferably 40 atom % or less. When the oxygen content at an interface of the light-modulation layer 30 on the catalyst layer 40 side is in the above-mentioned range, movement of hydrogen between the catalyst layer 40 and the light-modulation layer 30 is promoted, so that a light-modulation film having favorable light-modulation performance is obtained. In addition, as the oxygen content at an interface of the light-modulation layer 30 on the catalyst layer 40 side decreases, deterioration due to repetition of switching is reduced, so that a light-modulation film excellent in durability is obtained.

The oxygen content in the light-modulation layer 30 is determined by measuring a thickness-direction distribution (depth profile) of an element concentration by X-ray electron spectroscopy (XPS) while etching the light-modulation layer from the surface side (catalyst layer 40 side) toward the substrate side of the light-modulation film. The etching depth (nm) in the depth profile is calculated by multiplying an etching time (min) by a standard etching rate (nm/min) for SiO₂. In the resulting depth profile, a position which is situated between a layer adjacent to the light-modulation layer and the light-modulation layer and at which the concentration of an element contained in the largest amount in the layer adjacent to the light-modulation layer is a half value of the maximum value is defined as an interface between the light-modulation layer and the adjacent layer (start point and end point of the light-modulation layer). The distance between the start point of the light-modulation layer and a point at which the oxygen content is 50 atom % or more is defined as a thickness of the light-modulation region 32, and the thickness of a region where the oxygen content is 50 atom % or more is defined as a thickness of the oxidized region 31.

Although the thickness of the light-modulation layer 30 is not particularly limited, it is preferably 10 nm or more, more preferably 15 nm or more, further preferably 20 nm or more for improving the light shielding ratio (reflectance) in the reflective state (dehydrogenated state). When the thickness of the light-modulation layer is excessively small, the light reflectance in the reflective state tends to decrease, and when the thickness of the light-modulation layer is excessively large, the light transmittance in the transparent state tends to decrease. When the oxidized region is formed in the light-modulation layer 30, it is preferable the thickness of the light-modulation region 32 is in the above-mentioned range.

The surface irregularities of the light-modulation layer 30 tend to increase as the thickness becomes larger. When a light-modulation layer formed of a magnesium alloy or the like is deposited on the film substrate by sputtering, surface irregularities tend to be larger as compared to deposition on a glass substrate. This may be related to the fact that the film growth mode is changed by outgas from the film substrate to promote formation of surface irregularities.

When the surface irregularities of the light-modulation layer 30 increase, the surface irregularities of the catalyst layer 40 formed thereon tend to increase. When the catalyst layer 40 has large surface irregularities, the coverage with the surface layer 70 formed thereon may become uneven, leading to deterioration of the durability of the light-modulation film. Thus, the arithmetic mean roughness Ra of the surface (interface on the catalyst layer 40 side) of the light-modulation layer 30 is preferably 40 nm or less, more preferably 30 nm or less, further preferably 25 nm or less. The arithmetic mean roughness Ra of the light-modulation layer 30 can be calculated from a roughness curve of an interface in a TEM image of a cross-section of the light-modulation film.

For setting the arithmetic mean roughness of the surface within the above-described range, the thickness of the light-modulation layer 30 is preferably 200 nm or less, more preferably 100 nm or less, further preferably 80 nm or less, especially preferably 60 nm or less. In addition, if the thickness of the light-modulation layer is excessively large, the light transmittance in a transmission state (hydrogenated state) tends to decrease, and therefore the thickness of the light-modulation layer is preferably within the above-described range.

In sputtering deposition of the light-modulation layer on the film substrate, surface irregularities of the light-modulation layer tend to decrease when the deposition pressure is small. For decreasing the surface irregularities, the process pressure during deposition of the light-modulation layer is preferably 0.3 Pa or less, more preferably 0.25 Pa or less.

A metal target is used for deposition of the catalyst layer 40 on the light-modulation layer 30. The thickness of the catalyst layer is not particularly limited and can be appropriately set according to the reactivity of the light-modulation layer, the catalytic ability of the catalyst layer, and the like. The thickness is preferably 1 nm or more, more preferably 2 nm or more, further preferably 3 nm or more. The conditions for sputtering deposition of the catalyst layer are not particularly limited, and may be same or different from the conditions for deposition of the light-modulation layer 30. The pressure during deposition of the catalyst layer may be higher than the process pressure during deposition of the light-modulation layer.

By increasing the thickness of the catalyst layer, the catalyst capacity tends to be enhanced, leading to improvement of switching performance. In addition, by increasing the film thickness of the catalyst layer, the surface irregularities of the light-modulation layer 30 tend to be planarized, leading to a decrease in surface irregularities of the catalyst layer 40. The arithmetic mean roughness Ra of the surface of the catalyst layer 40 is preferably 16 nm or less, more preferably 14 nm or less, further preferably 12 nm or less. By reducing the arithmetic mean roughness Ra of the catalyst layer 40, deterioration of light-modulation performance in repetition of a hydrogenation and dehydrogenation cycles of the light-modulation film tends to be suppressed, leading to improvement of durability.

If the thickness of the catalyst layer 40 is excessively large, the catalyst layer 40 tends to act as a light blocking (light reflecting) layer, leading to a decrease in light transmittance of the light-modulation film even when the light-modulation layer 30 is in a hydrogenated state. The thickness of the catalyst layer 40 is preferably 30 nm or less, more preferably 10 nm or less, further preferably 8 nm or less, especially preferably 5 nm or less. For sufficiently exhibiting a function as a catalyst, the thickness of the catalyst layer is preferably 1 nm or more, more preferably 2 nm or more.

When the thickness of the catalyst layer 40 is increased, the surface irregularities of the light-modulation layer 30 are reduced, so that the arithmetic mean roughness Ra of the catalyst layer 40 can be decreased to improve the switching durability of the light-modulation film. On the other hand, if the thickness of the catalyst layer is excessively large as described above, light-modulation performance is deteriorated due to reduction of transparency. Thus, it is preferable to adjust the thickness of the catalyst layer 40 according to the size of irregularities of the light-modulation layer 30 so that the arithmetic mean roughness Ra falls within the above-described range without significantly reducing the transparency.

By reducing the relative ratio of the thickness of the light-modulation layer 30 to the thickness of the catalyst layer 40, the arithmetic mean roughness Ra of the catalyst layer 40 tends to decrease. The thickness of the light-modulation layer 30 is preferably 2 to 20 times the thickness of the catalyst layer 40. In other words, the ratio of the thickness of the light-modulation layer to the thickness of the catalyst layer (thickness ratio) is 2 or more and 20 or less. The thickness of the light-modulation layer 30 is preferably not more than 20 times, more preferably not more than 15 times, further preferably not more than 12 times the thickness of the catalyst layer 40. In addition, the thickness of the light-modulation layer 30 is preferably not less than 2 times, more preferably not less than 3 times, further preferably not less than 4 times the thickness of the catalyst layer 40.

For reducing the arithmetic mean roughness Ra of the catalyst layer 40, it is preferable to reduce surface irregularities of the light-modulation layer 30 which is an underlay of the catalyst layer 40. As described above, reduction of the pressure during sputtering deposition of the light-modulation layer 30 tends to decrease the surface irregularities of the light-modulation layer 30 and thus decrease the Ra of the catalyst layer 40 disposed thereon, leading to the switching durability of the light-modulation film.

<Surface Layer>

It is preferable that a surface layer 70 permeable to hydrogen is disposed on the catalyst layer 40. The surface layer is preferably one that is selectively permeable to hydrogen, and has low permeability to water and oxygen. By providing the surface layer 70, transmission of water and oxygen can be blocked to prevent oxidation of the light-modulation layer 30, leading to improvement of the cycle durability of the light-modulation film. In addition, by adjusting the refractive index and the optical thickness of the surface layer 70, light reflection at a surface of the light-modulation film can be reduced to increase the light transmittance in the transparent state.

As a materials of the surface layer 70, for example, an inorganic oxide may be used. Examples of the inorganic oxide include oxides of metal or semimetal elements such as Si, Ge, Sn, Pb, Al, Ga, In, Tl, As, Sb, Bi, Se, Te, Mg, Ca, Sr, Ba, Sc, Y, Ti, Zr, Hf, V Nb, Ta, Cr, Mo, W, Mn, Tc, Re, Fe, Ru, Os, Co, Rh, Ir, Ni, Pd, Pt, Cu, Ag, Au, Zn and Cd. The inorganic oxide layer may contain a mixed oxide of plurality of (semi)metals. As a material of the surface layer 70, an organic material such as a polymer, an organic-inorganic hybrid material, or the like may also be used.

The thickness of the surface layer 70 is not particularly limited, and can be appropriately set according to its purpose and so on. The thickness is, for example, about 10 nm to 300 nm. When the thickness of the surface layer is excessively large, permeation of hydrogen may be blocked, leading to deterioration of light-modulation performance and the switching speed, and therefore the thickness of the surface layer 70 is more preferably 200 nm or less, further preferably 150 nm or less, especially preferably 100 nm or less. The surface layer may include only one layer, or a plurality of layers. For example, when a plurality of thin-films having different refractive indices are stacked, and the optical thickness of each layer is adjusted, antireflection property can be improved to increase the light transmittance in the transparent state. In addition, durability can also be improved by combining an organic layer and an inorganic layer.

The surface layer 70 may be deposited by a dry process such as a sputtering method, or may be deposited by a wet method such as spin coating, dip coating, gravure coating or die coating. When the surface layer is formed of an organic material such as a polymer or the like, an organic-inorganic hybrid material or sol-gel material, it is preferable that deposition is performed by a wet method such as spin coating, dip coating, gravure coating or die coating.

Deposition of the surface layer 70 on the catalyst layer 40 having large surface irregularities by a wet method may cause generation of a thin portion or pinhole on a local basis, and thus decrease the barrier property against oxygen, moisture and the like, leading to deterioration of the switching durability of the light-modulation film. In the present invention, the covering property with the surface layer 70 can be made uniform to improve the cycle durability of the light-modulation film because of small arithmetic mean roughness of the surface of the catalyst layer 40 as described above.

<Other Additional Layers>

The light-modulation film according to the present invention may include layers other than the light-modulation layer 30, the catalyst layer 40 and the surface layer 70 on the polymer film substrate 10. For example, as in the case with the light-modulation film 3 shown in FIG. 3, an underlayer 20 may be disposed between the film substrate 10 and the light-modulation layer 30, or a buffer layer 50 may be disposed between the light-modulation layer 30 and the catalyst layer 40.

(Underlayer)

When the underlayer 20 is disposed on the film substrate 10, oxidation of an interface of the light-modulation layer 30 on the film substrate 10 side during deposition may be suppressed. In particular, when an inorganic oxide layer is formed as the underlayer 20 on the film substrate 10, outgas and transmitted gas from the film substrate 10 can be blocked to suppress oxidation of the light-modulation layer 30.

As the inorganic oxide, oxides of metal or semimetal elements such as Si, Ge, Sn, Pb, Al, Ga, In, Tl, As, Sb, Bi, Se, Te, Mg, Ca, Sr, Ba, Sc, Y, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn and Cd are preferably used. The inorganic oxide layer may contain a mixed oxide of plurality of (semi)metals. Among them, an oxide of Si, Nb, Ti or the like is preferable because it absorbs little light, and is excellent in gas barrier property against oxygen, water vapor and the like.

For imparting barrier property against a gas from the film substrate, the thickness of the underlayer 20 is preferably 1 nm or more. On the other hand, when the thickness of the underlayer is excessively large, the light transmittance tends to be reduced due to light absorption by an inorganic oxide, etc. which form the underlayer. Therefore, the thickness of the underlayer is preferably 200 nm or less. When the underlayer 20 has barrier property against a gas from the film substrate, formation of an oxidized region in the initial stage of deposition of the light-modulation layer is suppressed. In addition, when the oxidized region is not formed, or the thickness of the oxidized region is small, outgas from the film substrate 10 is blocked by the underlayer 20, and therefore oxidation of the light-modulation layer 30, which is caused by the outgas from the film substrate, can be suppressed to maintain high light-modulation performance.

When the underlayer is disposed between the film substrate and the light-modulation layer, a film substrate with the underlayer formed thereon beforehand may be used, or the underlayer may be deposited immediately before the deposition of the light-modulation layer by a sputtering method. When an underlayer of an inorganic oxide is deposited by a sputtering method, a metal target or an oxide target is used. When a metal target is used, sputtering deposition is performed while in addition to an inert gas such as argon, a reactive gas (e.g., oxygen) is introduced. When an oxide target is used, deposition is performed while an inert gas such as argon is introduced. When an oxide target is used, deposition may be performed while a reactive gas is introduced as necessary

(Buffer Layer)

When the buffer layer 50 is disposed between the light-modulation layer 30 and the catalyst layer 40, it is preferable the buffer layer 50 is permeable to hydrogen. The buffer layer may include only one layer, or a plurality of layers. For example, the buffer layer 50 may have a stacked structure of a layer having a function of suppressing migration of a metal from the light-modulation layer 30 and a layer suppressing passage of oxygen from the catalyst layer 40 side to the light-modulation layer 30.

When a metal thin-film consisting of Ti, Nb, V, an alloy of these metals, etc. is disposed as the buffer layer 50 between the light-modulation layer 30 and the catalyst layer 40, the switching speed from the transparent state to the reflective state in dehydrogenation tends to increase while migration of magnesium etc. from the light-modulation layer and the catalyst layer is suppressed.

When a metal thin-film including W, Ta, Hf, an alloy of these metals, etc. is disposed as the buffer layer 50, passage of oxygen to the light-modulation layer 30 from the catalyst layer 40 side can be suppressed to inhibit degradation of the light-modulation layer by oxidation. In addition, when a metal thin-film including a metallic material similar to that in the light-modulation layer is inserted as the buffer layer 50, the layer functions as a sacrificial layer which reacts with oxygen passing through the catalyst layer 40, so that oxidation of the light-modulation layer 30 can be suppressed. Preferably, the buffer layer acting as such a sacrificial layer is reversibly bonded with oxygen, and hydrogenated in hydrogenation of the light-modulation layer 30 (transparent state), so that the light transmittance increases. Thus, when a magnesium alloy is used for the buffer layer, the content of magnesium based on the total amount of metallic elements is preferably less than 50 atom %. The thickness of the buffer layer 50 is not particularly limited and can be appropriately set according to its purpose and so on. The thickness is, for example, 1 to 200 nm and is preferably 1 to 30 nm.

[Light-Modulation Element]

The light-modulation film of the present invention can be used for a hydrogen-activation-type light-modulation element capable of switching a light-transmissive state and a light-reflective state by hydrogenation and dehydrogenation of the light-modulation layer. The method for hydrogenating and dehydrogenating the light-modulation layer is not particularly limited. Examples thereof include a method in which the light-modulation film is exposed to a hydrogen atmosphere to hydrogenate the light-modulation layer, and the light-modulation film is exposed to an oxygen atmosphere (air) to dehydrate the light-modulation layer (gas chromic method); and a method in which the light-modulation layer 30 is hydrogenated and dehydrogenated using a liquid electrolyte (electrolytic solution) or a solid electrolyte (electrochromic method). Among them, the gas chromic method is preferable because it is possible to switch a light-modulation layer having a large area in a short time.

The light-modulation element including the light-modulation film can be applied to window panes of buildings and vehicles, shields for the purpose of protecting privacy, various kinds of decorations, lighting equipment, amusement tools and the like. Since a flexible substrate is used in the light-modulation film of the present invention, the light-modulation film is easily processed, and can be applied to a curved surface, resulting in excellent versatility. A light-modulation element using the light-modulation film of the present invention is hardly deteriorated even when switching between hydrogenation and dehydrogenation is repeated, and thus the element has high durability.

The light-modulation film of the present invention as it is may be used as a light-modulation element, or may be combined with a transparent member such as glass, a translucent member, an opaque member or the like to form a light-modulation element. In the light-modulation film of the present invention, the light-modulation layer can be transformed into a transparent state by hydrogenation to transmit light. Therefore, in a light-modulation element combined with a transparent member, switching between a transparent state and a reflective state can be performed by hydrogenation and dehydrogenation of the light-modulation layer.

When the light-modulation film is combined with other member to form a light-modulation element, it is preferable to fix the light-modulation film by bonding with an adhesive or an adhesive tape, or pinning for preventing displacement. As fixing means for fixing the light-modulation film and other member, an adhesive is preferable because the fixing area can be increased. As the adhesive, a pressure sensitive adhesive is preferably used. By providing a pressure sensitive adhesive on the polymer film substrate 10 of the light-modulation film 1 or 2 in advance, glass or the like and the light-modulation film can be easily bonded to each other. As the pressure sensitive adhesive, one having excellent transparency, such as an acryl-based pressure sensitive adhesive is preferably used.

### EXAMPLES

Hereinafter, the present invention will be described more in detail by showing examples, but the present invention is not limited to the following examples.

### Example 1

A roll of a 188 μm-thick polyethylene terephthalate (PET) film (manufactured by Mitsubishi Plastics, Inc.) was set in a roll-to-roll sputtering apparatus, and the inside of a sputtering apparatus was evacuated until the ultimate vacuum degree reached 5×10⁻³ Pa. The PET film substrate was conveyed in the sputtering apparatus without introducing a sputtering gas to perform degassing of the PET film substrate.

Thereafter, argon gas was introduced into the sputtering apparatus, the PET film was continuously conveyed at a rate of 1 m/minute, and on a deposition roll, a light-modulation layer consisting of Mg—Y alloy and a catalyst layer consisting of Pd were sequentially deposited on the PET film by DC sputtering. In deposition of the Mg—Y alloy layer, an Mg—Y split target (manufactured by RARE METALLIC Co., Ltd.) having an Mg metal plate and a Y metal plate at an erosion portion area ratio of 2:5 was used, and deposition was performed under conditions power density of 2000 mW/cm² and process pressure of 0.2 Pa. In deposition of the Pd layer, A Pd metal target (manufactured by Tanaka Kikinzoku Kogyo) was used, and deposition was performed under conditions power density of 300 mW/cm² and process pressure of 0.4 Pa. The thickness of the Mg—Y alloy layer was 40 nm, and the thickness of the Pd layer was 7 nm.

A titanium alkoxide solution was applied onto the Pd layer by spin coating, and a titanium oxide thin-film (surface layer) having a thickness of 50 nm was formed by a sol-gel method.

### Example 2

On each of the two cathodes arranged along a film substrate conveyance direction, the same Mg—Y split target as in Example 1 was disposed, and deposition was performed to make the thickness of the Mg—Y layer twice that in Example 1 (80 nm). Except for above, the same procedure as in Example 1 was carried out to produce a light-modulation film.

### Example 3 and Comparative Example 1

Except that the power densities for sputtering deposition of the Mg—Y layer and the Pd layer were changed to those shown in Table 1, the same procedure as in Example 2 was carried out to produce light-modulation films.

### Comparative Example 2

Except that the flow rate of argon was adjusted to change the process pressure during sputtering deposition of the Mg—Y layer to 0.4 Pa, the same procedure as in Example 3 was carried out to produce a light-modulation film.

[Evaluation]

### (Thickness and Surface Shape)

The thickness of each of the Mg—Y layer (light-modulation layer) and the Pd layer (catalyst layer) was determined from a TEM image of a cross-section. A three-dimensional surface shape of the light-modulation film before formation of the surface layer was measured under the conditions of object lens magnification: 10 times, zoom lens magnification: 20 times and measurement area: 0.35 mm×0.26 mm with a coherence scanning interferometer (Zygo NewView 7300). From the obtained three-dimensional surface shape, a roughness curve was extracted, and the arithmetic mean roughness Ra of the Pd layer surface was calculated in accordance with JIS B0601. In the analysis, a program equipped to the apparatus was used to make corrections under the following conditions.

Removed: None

Filter: High Pass

Filter Type: Gauss Spline

Low wavelength: 300 μm

Remove spikes: on

Spike Height (xRMS): 2.5

(Thickness of Oxidized Region in Light-Modulation Layer)

An oxygen concentration distribution in the light-modulation layer was determined by performing depth profile measurement using a scanning X-ray photoelectron spectrometer equipped with an Ar ion etching gun (“Quantum 2000” manufactured by ULVAC-PHI, Inc.). In analysis of the depth profile, a position which is situated between the light-modulation layer and the catalyst layer and at which the Pd element concentration is a half value of the maximum value of the Pd element concentration in the catalyst layer was defined as an interface between the catalyst layer and the light-modulation layer (start point of the light-modulation layer); and a position which is situated between the light-modulation layer and the polymer film substrate and at which the C element concentration is a half value of the maximum value of the C element concentration in the polymer film substrate was defined as an interface between the light-modulation layer and the polymer film substrate. The thickness (depth) in the depth profile was calculated by converting the etching time into the depth on the basis of the Ar ion etching rate of the silicon oxide layer.

(Initial Light Modulation Performance)

A light-modulation film was exposed to a hydrogen gas atmosphere at 1 atm with the hydrogen gas diluted to 1% by volume with argon, and transmittance was measured under a hydrogen gas atmosphere. Thereafter, the light-modulation film was dehydrated by returned to an air atmosphere, and the light transmittances was measured again. For measurement of the light transmittance, a light emitting diode (EL-1KL3 (peak wavelength: about 940 nm) manufactured by KODENSHI CORP.) was used as a light source, and a photodiode (SP-1ML manufactured by KODENSHI CORP.) was used as a light receiving element. There is almost no difference between transmittances of the light-modulation film at a wavelength of 940 nm and at a wavelength of 750 nm which corresponds to a visible light region. The light transmittances difference ΔT between the hydrogenated state (transparent state) and the dehydrogenated state (reflective state) was defined as initial light-modulation performance.

(Evaluation of Cycle Characteristics)

The film substrate-side surface of the light-modulation film of each of Examples and Comparative Examples was bonded onto a glass plate with an acrylic transparent pressure sensitive adhesive interposed therebetween, and another glass plate was disposed thereon with a spacer interposed therebetween to produce a light-modulation element for evaluation. A predetermined amount of hydrogen-containing gas was caused to flow from a mass flow controller to the light-modulation element for evaluation for 30 seconds, the flow of the hydrogen-containing gas was then stopped for 2 minutes, and air was caused to flow in through a gap between the two glass plates. 2000 cycles of flow control of the hydrogen-containing gas were performed with the above-mentioned process as one cycle, the light-modulation performance (light transmittance difference ΔT between the hydrogenated state and the dehydrogenated state) was measured in the same manner as in the measurement of the initial light-modulation performance.

Table 1 shows the deposition conditions for each layer, the film thickness of each layer, the arithmetic mean roughness Ra of the Pd layer and the light-modulation performance (initial light-modulation performance and after cycle test) in the light-modulation films of Examples and Comparative Examples.

TABLE 1

| | | | | | | | | | | Light-modulation | |
|---|---|---|---|---|---|---|---|---|---|---|---|
| | Deposition conditions | | | | | | | | | performance ΔT | |
| | | Process | | Power | | Thickness and surface shape | | | | | After |
| | Number | pressure | | density | | Thickness | | Thickness | Ra | | cycle |
| | of Mg-Y | (Pa) | | (mW/cm²) | | (nm) | | ratio | (nm) | Initial | test |
| | cathodes | Mg-Y | Pd | Mg-Y | Pd | Mg-Y | Pd | Mg-Y/Pd | Pd | (%) | (%) |
| Example 1 | 1 | 0.2 | 0.4 | 3000 | 300 | 40 | 7 | 5.7 | 9.1 | 20 | 20 |
| Example 2 | 2 | 0.2 | 0.4 | 3000 | 300 | 80 | 7 | 11.4 | 11.1 | 25 | 25 |
| Example 3 | 2 | 0.2 | 0.4 | 2000 | 200 | 60 | 3 | 20.0 | 15.2 | 28 | 15 |
| Comparative | 2 | 0.2 | 0.4 | 3000 | 200 | 80 | 3 | 26.7 | 18.2 | 35 | 5 |
| Example 1 | | | | | | | | | | | |
| Comparative | 2 | 0.4 | 0.4 | 2000 | 200 | 60 | 3 | 20.0 | 16.2 | 28 | 10 |
| Example 2 | | | | | | | | | | | |

The light-modulation film of Comparative Example 1 was excellent in initial performance, but had significantly low light-modulation performance after the cycle test since the Pd catalyst layer had a small thickness and the light-modulation layer had a large thickness. In Example 3 where the thickness of the light-modulation layer was smaller as compared to Comparative Example1, the surface irregularities of the Mg—Y layer were reduced, so that the arithmetic mean roughness Ra of the Pd layer formed thereon was small, and the cycle durability was improved as compared with Comparative Example 1.

In Example 2 where the thickness of the catalyst layer was larger than that in Comparative Example 1, the increase in the thickness of the Pd layer reduced the surface irregularities of the Mg—Y layer, so that the arithmetic mean roughness Ra of the Pd layer decreased, and thus light-modulation performance was not deteriorated even after 2000 cycles. In Example 1 where the thickness of the Mg—Y layer was smaller than that in Example 2, light-modulation performance was not deteriorated after the cycle test as in Example 2.

The above results show that by adjusting the ratio of the thickness of the light-modulation layer to the thickness of the catalyst layer, the surface roughness of the catalyst layer is reduced to enhance the covering property with the surface layer disposed thereon, so that the cycle durability of the light-modulation film can be improved.

Comparison of Example 3 with Comparative Example 2 shows that there was no difference in thickness of each layer but the arithmetic mean roughness Ra of the Pd layer was smaller and light-modulation performance after the cycle test was higher in Example 3 where the Mg—Y was deposited under low pressure. These results show that by decreasing the sputtering deposition pressure of the light-modulation layer, the arithmetic mean roughness Ra of the catalyst layer formed thereon is reduced, so that the cycle durability of the light-modulation film can be improved.

### DESCRIPTION OF REFERENCE CHARACTERS

1, 2 light-modulation film

10, 12 polymer film substrate

30 light-modulation layer

31 oxidized region

32 light-modulation region

20 underlayer

40 catalyst layer

50 buffer layer

70 surface layer

1. A light-modulation film comprising:
a polymer film substrate; and
a light-modulation layer and a catalyst layer arranged in this order on the polymer film substrate, where the light-modulation layer reversibly changes in state between a transparent state by hydrogenation and a reflective state by dehydrogenation, and the catalyst layer promotes hydrogenation and dehydrogenation of the light-modulation layer,
wherein an arithmetic mean roughness of a surface of the catalyst layer is 16 nm or less.

2. The light-modulation film according to claim 1, wherein a thickness of the light-modulation layer is 2 to 20 times a thickness of the catalyst layer.

3. The light-modulation film according to claim 1, further comprising a surface layer disposed on the catalyst layer.

4. The light-modulation film according to claim 3, wherein a thickness of the surface layer is 10 to 300 nm.

5. The light-modulation film according to claim 1, wherein the light-modulation layer is a thin-film containing metal selected from the group consisting of a rare earth metal, an alloy of a rare earth metal and magnesium, an alloy of alkaline earth metal and magnesium, and an alloy of a transition metal and magnesium, or a hydride or an oxide thereof.

6. A method for manufacturing the light-modulation film set forth in claim 1, wherein
the catalyst layer is formed by a sputtering method, and a pressure during deposition of the catalyst layer is 0.3 Pa or less.

7. The method for manufacturing the light-modulation film according to claim 6, wherein the light-modulation layer is formed by a sputtering method.

8. The method for manufacturing the light-modulation film according to claim 7, wherein a pressure during deposition of the light-modulation layer is smaller than the pressure during deposition of the catalyst layer.

9. The method for manufacturing the light-modulation film according to claim 6, wherein a surface layer having a thickness of 10 to 300 nm is further formed on the catalyst layer by a wet method.
